(19) United States
(12) Patent Application Publication
(10) Pub. No.: US 2008/0182407 A1
(43) Pub. Date: Jul. 31, 2008

(54) METHOD OF FORMING VIAS IN A SEMICONDUCTOR DEVICE

(75) Inventors: Jun Zhai, San Jose, CA (US); Christy Woo, Cupertino, CA (US); Kok-Yong Yiang, Santa Clara, CA (US); Paul R. Besser, Sunnyvale, CA (US); Richard C. Blish, Saratoga, CA (US); Christine Hau-Reige, Fremont, CA (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: ADVANCED MICRO DEVICES, INC., Sunnyvale, CA (US)

(21) Appl. No.: 11/669,700

(22) Filed: Jan. 31, 2007

(51) Int. Cl. H01L 21/4763

(52) U.S. Cl. 438/639; 257/E21.495

(57) ABSTRACT

A via is formed in contact with a conductive line, whereby the via is offset from the conductive line so that the via extends beyond the conductive line. In accordance with a specific embodiment, a portion of the via contacts a sidewall of the conductive line.

### FIELD OF THE DISCLOSURE

The present disclosure is related to devices having via interconnects, and particularly to integrated circuit devices having offset via connections.

### DESCRIPTION OF THE RELATED ART

During the manufacture of integrated circuit devices, individual semiconductor components fabricated at a substrate are connected together using conductive lines and vias to implement a desired function. The process of forming connections between components is generally referred to as metallization and can include connections at multiple interconnect levels. One type of interconnect level, generally referred to as a metal level, contains a plurality of conductive lines separated from each other by dielectric material. Conductive lines at different levels can be electrically connected to each other through conductive structures referred to as vias that are formed within a dielectric material residing between metal levels.

An ideal contact between a via and a conductive line provides a low-resistance interface with low susceptibility to electromigration. While an interface at the time of manufacture may provide an adequate contact between a via and the conductive line that it contacts, stresses at the via/conductive line interface can result in peeling at the interface, which can facilitate undesirable electromigration over time. It has been observed that near-borderless vias demonstrate significantly higher stresses at their interface with conductive lines than do borderless vias, thereby resulting in additional reliability concerns. Therefore, a method and apparatus that improves the reliability of the electrical connection at the via/conductive line interface for near-borderless vias, and other vias, would be useful.

### BRIEF DESCRIPTION OF THE DRAWINGS

The present disclosure may be better understood, and its numerous features and advantages made apparent to those skilled in the art by referencing the accompanying drawings.

FIG. 1 includes an plan view of vias contacting a metal line;

FIGS. 2-4 include cross-sectional views at specific locations of FIG. 1;

FIG. 5 includes a flow diagram of a method in accordance with a specific embodiment of the present disclosure;

FIG. 6 includes a cross-sectional view of a substrate at which semiconductor transistors and interconnect structures are formed in accordance with a specific embodiment of the present disclosure;

FIG. 7 includes a cross-sectional view of a specific embodiment of a portion of FIG. 6;

FIG. 8 includes a cross-sectional view of a specific embodiment of a portion of FIG. 6;

FIG. 9 includes a three-dimensional perspective of a via contacting a conductive line;

FIG. 10 includes a cross-sectional view of a via and a conductive line in accordance with a specific embodiment of the present disclosure;

FIG. 11 includes a cross-sectional view of a via and a conductive line in accordance with a specific embodiment of the present disclosure;

FIG. 12 includes a flow diagram of a method in accordance with a specific embodiment of the present disclosure;

FIG. 13 includes a cross-sectional view of a specific embodiment in accordance with the present disclosure.

The use of the same reference symbols in different drawings indicates similar or identical items.

### DETAILED DESCRIPTION

In accordance with a specific embodiment of the present disclosure, a via is formed in contact with a conductive line, whereby the via is offset from the conductive line so that the via extends beyond an upper surface of the conductive line. In accordance with a specific embodiment, a portion of the via contacts a sidewall of the conductive line. The use of an offset via reduces stress at the interface between the via and conductive line, as compared to a borderless via, and facilitates positive shunting of current between the via and the conductive line.

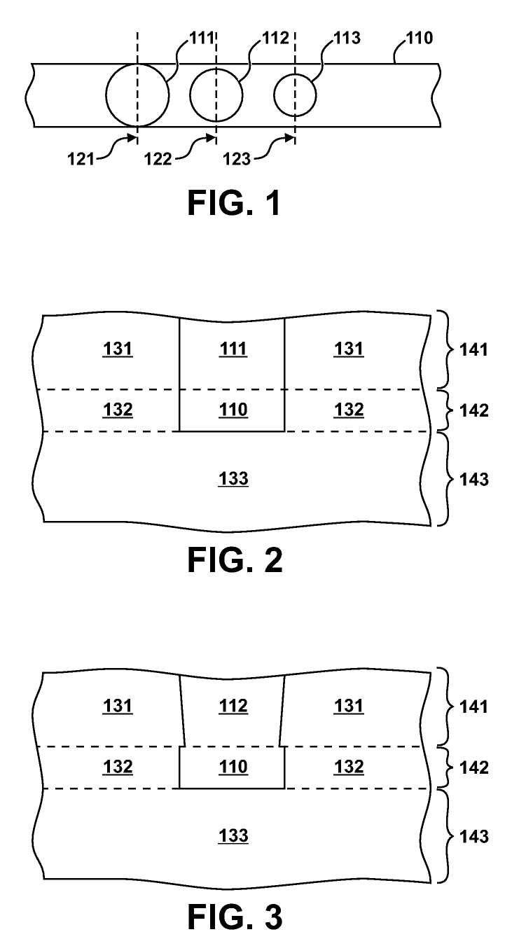

Specific embodiments of the present disclosure will be better understood with reference to FIGS. 1-13 herein.

A via typically has a width that is the same as, or smaller than a conductive line to which it contacts. The term “borderless via” is intended to mean a via having an outer vertical edge (sidewall) that is aligned to a sidewall of a conductive line to which it contacts such that the outer vertical edge of the via and the sidewall of the conductive line are in a common plane defined by the sidewall of the conductive line as illustrated by via 111 illustrated at FIG. 1 and FIG. 2. Specifically, FIG. 1 illustrates a plan view of a borderless via 111 with respect to conductive line 110, while FIG. 2 illustrates a cross-sectional view of borderless via 111 and conductive line 110 at cross-section 121 of FIG. 1. At FIG. 2, via 111 is between dielectric material 131 at level 141. Conductive line 110 is between dielectric material 132 at level 142 and overlies dielectric material 133 at level 143. In the illustrated embodiment, the width of via 111 is substantially the same as the width of conductive line 110 (i.e., the via width/line width ratio is 1:1). Via 111 is a borderless via having substantially the same width as the conductive line, resulting in an outer edge that is coincident planes defined by opposing sidewalls of the conductive line 110. The via 111 is substantially the same width, e.g. at least 99% the width, of the conductive line. Note that dashed lines in the cross-sectional figures illustrated herein indicate a boundary between two regions have a similar conductive characteristic. For example, there is a dashed line between conductive line 110 and via 111 because both regions are conductive. Similarly, there is a dashed line between dielectric 132 and adjacent dielectrics 131 and 133 because each of these regions is non-conductive (i.e., a dielectric).

The term “near-borderless via” is intended to mean a via having one or more outer vertical edges that are formed slightly within the outer edges of the conductive line as illustrated by via 112 at FIG. 1 and FIG. 3. FIG. 1 illustrates a plan view of a borderless via 112 with respect to conductive line 110, while FIG. 3 illustrates a cross-sectional view of near borderless via 112 and conductive line 110 at cross section 122 of FIG. 1. The width of via 112 is slightly smaller than the width of conductive line 110. A via is considered near borderless when its width is 80%-99% the width of the conductive line. Note that it will be appreciated that while the vias herein are illustrated as being cylindrical in nature, they can be rectangular in shape as well.

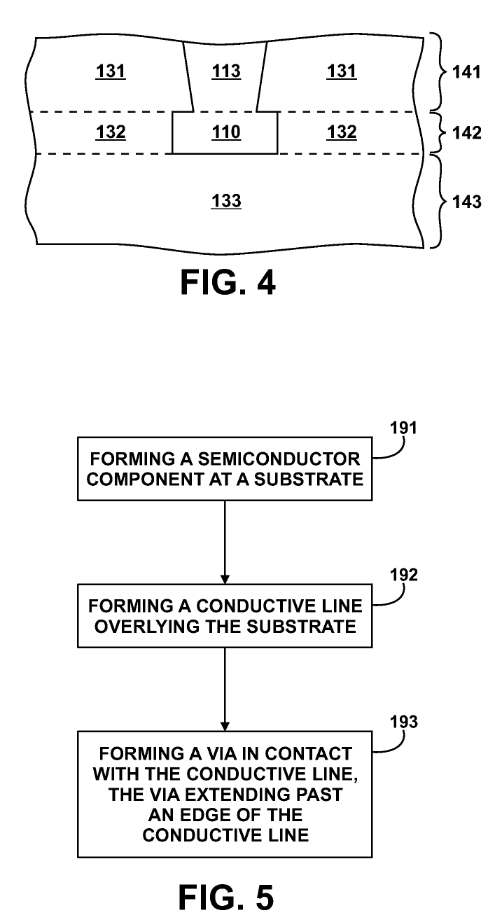

The term “bordered via” is intended to mean a via that contacts the conductive line such that the edges of the via are well within the outer edges of the conductive line as illustrated by via 113 at FIG. 1 and FIG. 4. FIG. 1 illustrates a plan view of a bordered via 113 with respect to conductive line 110, while FIG. 4 illustrates a cross-sectional view of bordered via 113 and conductive line 110 at line 123 of FIG. 1. The width of via 113 is significantly smaller than the width of conductive line 110. A via is considered bordered when its width is less than 80% the width of the conductive line that it contacts.

A via having a width about the same as the width of its conductive line is often used when the conductive line carries a signal between components (a signal line). A via having a width significantly less than its conductive line is often used when the conductive line provides a voltage reference, such as Vdd or GND, to many components.

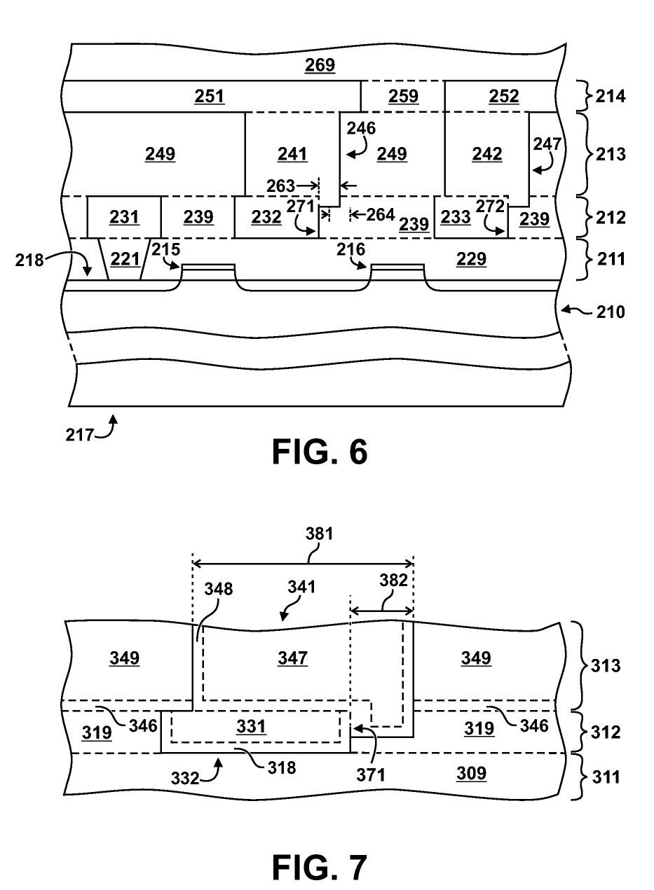

The term “substrate” as used herein is intended to mean a base material that can be either rigid or flexible and may include one or more layers of one or more materials, which can include, but is not limited to, one or more of semiconductor, dielectric, polymer, metal, ceramic materials, or combinations thereof. The reference point for a substrate is the beginning point of a process sequence. For example, FIG. 6 illustrates a substrate 210, which can be a bulk semiconductor substrate, a semiconductor on insulator substrate, or the like.

The term “substrate surface” is intended to refer to a major surface of the initial base material of the substrate. For example, substrate 210 of FIG. 6 has a bottom surface 217, and a top surface 218 at which transistors 215 and 216 are formed.

The term “surface,” with respect to a structure formed at a substrate, is intended to refer to one of two surfaces substantially parallel to the substrate surfaces. The term “top surface,” with respect to a surface of a structure formed at a substrate, is intended to refer to a surface of the structure that is substantially parallel to a substrate surface and furthest from the substrate. The term “bottom surface,” with respect to a surface of a structure formed at a substrate, is intended to refer to the surface of the structure that is substantially parallel to a substrate surface and closest to the substrate. With respect to the conductive line 411 illustrated at FIG. 9, a top surface 423 is defined by the length 441 and width 442 of conductive line 411.

The term “side wall,” with respect to a structure formed at a substrate, is intended to refer to a surface substantially perpendicular the structure's top and bottom surface. With respect to FIG. 9, a sidewall 422 is defined by the length 441 and height 443 of conductive line 411. FIG. 9 illustrates a second sidewall 421 that is defined by the width 442 and height 443 of conductive line 411. Note that via 412 also has sidewall surfaces.

The terms “height,” “length,” and “width,” when referring to a structure overlying a substrate, are intended to refer to dimensions substantially perpendicular to each other. “Height” is intended to refer to a dimension substantially perpendicular to the substrate surface at which it is formed. For example, with reference to FIG. 9, a height 443 is illustrated for conductive line 411. “Length” is intended to refer to a dimension within a plane substantially parallel to the substrate surface. “Width” is intended to refer to a dimension within the same plane as the length and parallel to the substantially perpendicular to the “length” dimension. For example, with reference to FIG. 9, a length 441 and width 442 are illustrated for conductive line 411. In one embodiment, the “width” is shorter than the “length.”

FIG. 5 includes a flow diagram in accordance with a specific embodiment of the present disclosure. At block 191, a semiconductor component is formed at a substrate. For example, referring to FIG. 6, transistors 215 and 216 have been formed at substrate 210.

At block 192 of FIG. 5 a conductive line is formed overlying the substrate. Referring to FIG. 6, conductive lines 231-233 and 251-252 are formed at substrate 210 such that they overlying substrate 210 and transistors 215 and 216 also formed at substrate 210. A dielectric material 229 is formed at level 211 to separate conductive lines 231-233 from the surface of the substrate 210 and structures formed thereon. A dielectric material 239 is formed at level 212 to separate conductive lines 231-233 from each other. Note that conductive structure 221, referred to as a contact, contacts conductive line 231 and a source/drain region of transistor 215.

At block 193 of FIG. 5, vias are formed that are offset from, and make contact to, conductive lines 232 and 233. For example, referring to FIG. 6, the via 241 is offset from the conductive line 232 in that via 241 extends past an edge 271 of the conductive line 232 (e.g., a bottom surface of the via 241 extents past a top surface of the conductive line 232). Therefore, the via 241 directly overlies the sidewall of conductive line 232. In the specific embodiment of FIG. 6, vias 241 and 242 have been offset in a horizontal direction from conductive lines 232 and 233, respectively, by an amount 263. Dimension 264 represents the horizontal range where sidewall 246 of the via 241 can reside due to unintentional random process variations that can occur during manufacturing between the vias at level 213 and conductive lines at level 212. Note that regardless of the amount of unintentional misalignment 263, the vias 241 and 242 are offset from conductive lines 232 and 233 sufficiently to assure they will extend beyond conductive lines 232 and 233 after manufacturing. As a result, the right-most sidewalls 246 and 247 of vias 241 and 242, respectively, do not immediately overlie metal lines 232 and 242. This results in only a portion of a bottom surface of via 241 being in contact with the top surface of conductive line 232, and only a portion of a bottom surface of via 242 being in contact with the top surface of conductive line 233. Note that a dielectric material 249 is formed at level 213 to separate vias from each other, and that dielectric material 259 is formed at level 214 to separate conductive lines from each other. Layer 269 represents a dielectric that can be associated with another interconnect layer or a passivation layer

FIG. 7 illustrates a specific interconnect embodiment in accordance with the present disclosure. For example, FIG. 7 illustrates a more detailed view of a conductive line 332, which can correspond to conductive line 232 or 233 of FIG. 6.

In accordance with a specific embodiment, an opening is formed in a material at level 312 to define conductive line 332. In one embodiment, conductive line 332 is formed at level 312 and includes a barrier layer 318 (outer layer) and core layer 331, whereby the core layer 331 is isolated from dielectric layer 319 by barrier layer 318. After formation of conductive line 332, a dielectric is formed at level 313 overlying conductive line 332. The dielectric at level 313 is illustrated to include an etch stop layer 346 and a dielectric layer 349 that can be etched selectively relative the etch stop layer 346. A via opening that is offset relative to the conductive line is formed using a stencil mask to pattern a resist layer. In the specific embodiment, the via opening is formed through level 313 and into level 312 to expose a sidewall portion of the conductive line 332. Note that in the illustrated embodiment an over etch is performed after detection of etch stop layer 346. A via 341 that electrically contacts the conductive line 332 is formed through level 313 and into level 312. Note that only a portion of the bottom surface of via 341 is in contact with the top surface of conductive line 332. In a specific embodiment, via 341 includes a barrier layer 348 and a conductive core 347, such as copper, aluminum, and the like.

In accordance with a specific embodiment, the offset distance 382 of via 341 is between 10% and 40% of the total width 381 of the via 341 as measured along a dimension perpendicular to the side surface of the conductive line. Note with respect to FIG. 7 the dimension perpendicular to the side surface of the conductive line lies within the cross-sectional plane (i.e., the surface of the drawing sheet containing FIG. 7). In accordance with another embodiment, the offset distance 382 of via 341 is between 10% and 35% of the total width 381 of the via as measured along a dimension perpendicular to the side surface of the conductive line. In accordance with another embodiment, the intentional misalignment of via 341 is between 10% and 30% of the total width 381 of the via 341 as measured along a dimension perpendicular to the sidewall of the conductive line. In accordance with another embodiment, the offset of via 341 is between 10% and 25% of the total width 381 of the via 341 as measured along a dimension perpendicular to the sidewall of the conductive line. In accordance with another embodiment, the offset of via 341 is between 10% and 20% of the total width 381 of the via 341 as measured along a dimension perpendicular to the sidewall of the conductive line.

Selection of a via offset sufficiently large to accommodate formation of a flat via bottom within layer 312 is more desirable than a via offset that results in a rounded narrower bottom within layer 312 that is more rounded.

Conductive line 332 includes a conductive core layer 331 and a conductive barrier layer 318. The barrier layer 318 is made from a material different than the core layer 331 and the dielectric layer 319. The barrier layer prevents contamination between conductive core 331 and adjacent dielectric 319 materials. Similarly, via 341 includes a conductive core layer 347 and a conductive barrier layer 348. The barrier layer 348 is made from a material different from the core layer 347. A sidewall of the via 341 is defined by the interface of the barrier layer 348 and the dielectric 349. Conductive cores 331 and 347 can include one or more conductive materials including a metal-containing component, a metal, or a metal alloy. Suitable metals can include transition metals, such as copper, aluminum, or the like. In an alternate embodiment, the conductive line of FIG. 7 can be formed without inclusion of a barrier layer when the conductive core material is compatible with its surrounding dielectric material.

FIG. 7 further illustrates via 341 offset from conductive line 332 by a distance 382 that extends past a sidewall 371 of conductive line 332. The term “intentional offset,” with respect to a via and a conductive line, is intended to refer to an offset amount that results in a via that extends beyond an outer boundary of the conductive line defined by a sidewall of the conductive line regardless of any expected unintentional misalignment due to random process variation. For example, if the random process misalignment variation between the via 341 and the conductive line 332 is ±1 nm, the amount of offset needed to assure the via 341 is intentionally offset, i.e., extends beyond conductive line 332 in a desired direction (i.e., to the right in FIG. 7), needs to be greater than the possible random misalignment (±1 nm) that can occur in the opposite direction.

The via 341 includes a conductive core layer 347 and a conductive barrier layer 348. The conductive core 347 and barrier layer 348 are formed from different materials and perform similar functions as previously described with respect to conductive line 332. In an alternate embodiment, the barrier layer 348 can include a thin adhesion layer formed on the conductive line 332 and on the exposed dielectric materials at levels 312 and 313 to facilitate adhesion of subsequently deposited material. According to a particular embodiment, adhesion metals can include nitrogen-containing components, such as those including transition metals, and particularly tantalum nitride (TaN), titanium nitride (TiN), tungsten nitride (WN) and the like. These nitrogen-containing compounds have good adhesion to the dielectric materials and provide good barrier resistance to the diffusion of copper from the copper conductor materials to the surrounding dielectric material. High barrier resistance with conductor materials, such as copper, helps to prevent diffusion of subsequently deposited conductive material into the dielectric layer, which can cause short circuits in the integrated circuit. However, some of these nitride barrier materials have relatively poor adhesion to copper and relatively high electrical resistance. Because of these drawbacks, pure refractory metals such as tantalum (Ta), titanium (Ti), tungsten (W), and the like can be formed at an adhesion layer of barrier layer 348. The refractory metals are good barrier materials, generally having lower electrical resistance than nitride barrier materials, and having good adhesion to copper. It will be appreciated, that in some cases, the barrier material has sufficient adhesion to the dielectric material that the adhesion layer is not required, and in other cases, the adhesion and barrier material become integral. The term “barrier layer,” as used in reference with vias and conductive lines, is intended to refer collectively to the adhesion and barrier materials describe above.

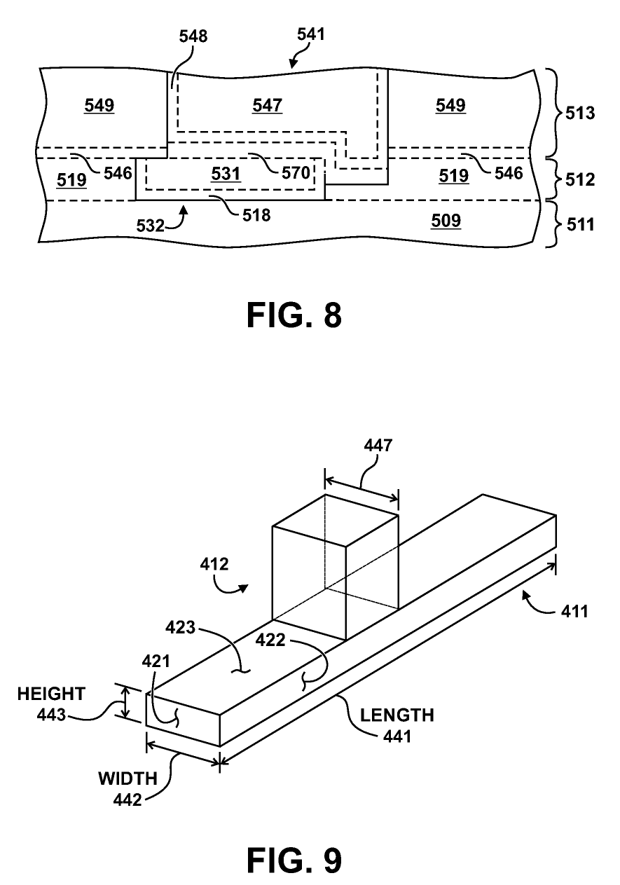

FIG. 8 illustrates a specific interconnect embodiment in accordance with the present disclosure. For example, FIG. 8 illustrates a more detailed view of a conductive line 532, which can correspond to conductive lines 232 and 233 of FIG. 6. A shunt layer, such as layer 570 of FIG. 8, is a portion of via 541 formed between core layer 547 of via 541 and the core layer 531, of the conductive line 532 to improve shunting from the via 541 to the conductive line 532. In one embodiment, the shunting layer is a material that does not mix with the material of core layer 531 or the overlying via materials, has a higher melting point than the material of core layer 531 and the overlying via materials so that its electromigration resistance is high, and has a lower electrical resistance than adjacent conductive material. Note that the shunt layer 570 and the material between itself and the conductive layer 547, if any, of the via all form part of the via 541. While shunt materials can include barrier materials, a preferred shunt material includes ruthenium (Ru) that can be deposited using long-throw, no-bias, physical vapor deposition. It will be appreciated that if PVD material is deposited that some of this material reside on the sidewall as 548. In general, however, the bottom step coverage, represented by shunt layer 570 is higher than the sidewall step coverage. It will be appreciated that the combination of shunt layer 570 and the barrier layer 548 form a combined shunting layer.

The formation and use of intentionally offset vias that extend past a sidewall edge of the conductive line to which they contact improves electromigration characteristics of semiconductor devices using borderless and near-borderless vias. For example, these improvements increase the amount of interface linkage at the metal etch stop/conductive line interface, thereby reducing peeling stress between the etch stop layer and the via. In addition, the formation and use of vias extending beyond the edge of the conductive line also promotes a positive shunting effect. The minimum pitch between vias can be maintained by applying the offset to all vias at a common level to avoid adversely affecting dielectric breakdown.

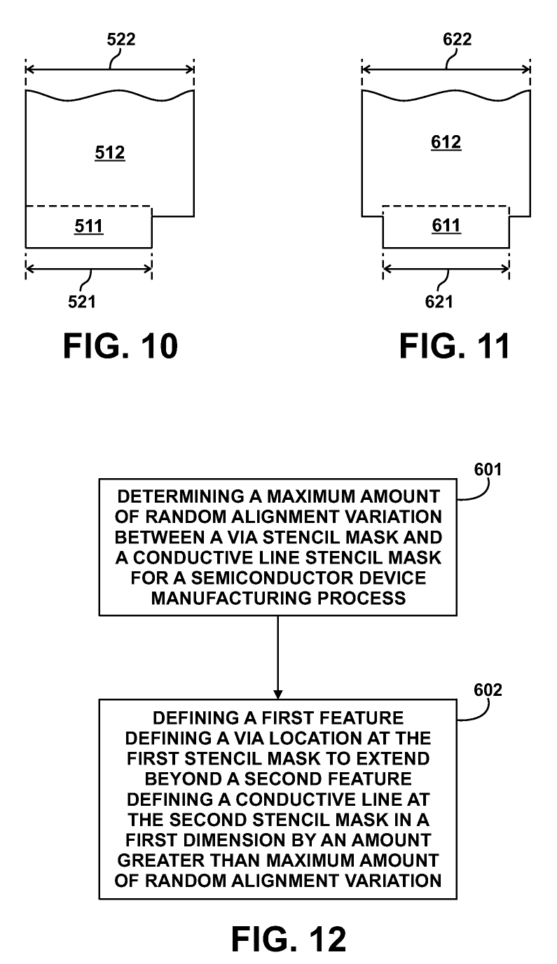

FIG. 10 illustrates an alternate embodiment in accordance with the present disclosure, whereby the via 512 has a dimension 522 that is larger than the width 521 of the conductive line 511 that it contacts, thereby extending beyond an edge of the conductive line 511. In the specific embodiment illustrated in FIG. 10, a portion of via 512 contacts a sidewall of conductive line 511.

FIG. 11 illustrates an alternate embodiment in accordance with the present disclosure, whereby the via 612 has a dimension 622 that is larger than the width 621 of the conductive line 611 and extends beyond both illustrated edges of the conductive line 611. In the specific embodiment illustrated in FIG. 10, a portion of via 612 contacts two opposing sidewall locations of conductive line 611.

FIG. 12 illustrates a method in accordance with a specific embodiment of the present disclosure. At 601 a maximum amount of random alignment variation between a via stencil mask and a conductive line stencil mask for a semiconductor device manufacturing process is determined. It will be appreciated that all features formed at a stencil mask are subject to the same amount of random alignment variation with respect to another stencil mask. For example, alignment features, such as alignment marks and overlay metrology marks that are typically placed in the scribe lines, and features defining electronic device structures are subject to the same amount random alignment variation.

At 602, a first feature of the first stencil mask is defined. The first feature defining a via location for a semiconductor device interconnect. The first feature at the first stencil mask intentionally offset from a second feature of the second stencil mask that defines a conductive line. The intentional offset being an amount greater than maximum amount of random alignment variation to assure the first feature is offset from an edge of the second feature.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, principles of the invention have been described above in connection with specific embodiments. However, one of ordinary skill in the art appreciates that one or more modifications or one or more other changes can be made to any one or more of the embodiments without departing from the scope of the invention as set forth in the claims below. For example, it will be appreciated that in various embodiments, the barrier layers are of materials such as tantalum (Ta), titanium (Ti), tungsten (W), compounds thereof, and combinations thereof. The seed layers (where used) are of materials such as copper (Cu), gold (Au), silver (Ag), compounds thereof and combinations thereof with one or more of the above elements. The conductor cores with or without seed layers are of materials such as copper, aluminum (Al), gold, silver, compounds thereof, and combinations thereof. The dielectric layers are of dielectric materials such as silicon oxide (SiO), tetraethoxysilane (TEOS), borophosphosilicate (BPSG) glass, etc. with dielectric constants from 4.2 to 3.9 or low dielectric constant dielectric materials such as fluorinated tetraethoxysilane (FTEOS), hydrogen silsesquioxane (HSQ), benzocyclobutene (BCB), etc. with dielectric constants below 3.9. The stop layers and capping layers (where used) are of materials such as silicon nitride (Siₓ Nₓ) or silicon oxynitride (SiON).

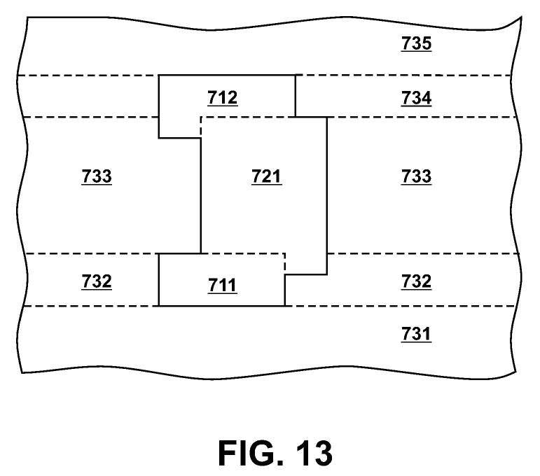

It will be further appreciated that the vias can be formed as part of a dual inlaid process, or formed separately from overlying conductive lines. When the via is formed separate from the overlying conductive line, the via can be offset from both conductive lines. For example, FIG. 13 illustrates a via 721 offset from an overlying conductive line 712 and from an underling conductive line 711. Dielectric materials 731-735 are illustrated as being formed at various levels of the device portion of FIG. 13.

Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

What is claimed is:

1. A method comprising:
forming a conductive line overlying a semiconductor device at a substrate, the conductive line comprising a top surface and a side wall; and
forming a via having a bottom surface in contact with the first conductive line, the bottom surface extending beyond the top surface of the conductive line.

2. The method of claim 1 wherein forming the via further comprises forming the via in contact with the sidewall of the conductive line.

3. The method of claim 2 wherein the conductive line comprises a core layer and a barrier layer, the sidewall of the conductive line being defined by the barrier layer, wherein a material of the core layer is different than a material of the barrier layer.

4. The method of claim 3 wherein the via comprises a core layer and a outer layer, the bottom surface of the via being defined by the outer layer, wherein a material of the core layer is different than a material of the outer layer.

5. The method of claim 4 wherein the outer layer is a barrier layer of the via.

6. The method of claim 4 wherein the outer layer is a shunting layer of the via having a higher melting point than the core layer of the via.

7. The method of claim 1 wherein forming the via further comprises forming the via to have sidewall extending beyond an edge defining the top surface, wherein the via directly overlies a sidewall of the conductive line.

8. The method of claim 1 wherein forming the via further comprises the bottom surface of the via extending beyond the top surface to directly overly the sidewall of the conductive line.

9. The method of claim 1 wherein forming the via further comprises the bottom surface of the via extending beyond the top surface of the conductive line by 10%-40% of the via as measured along a dimension perpendicular to the sidewall of the conductive line.

10. The method of claim 1 wherein forming the via further comprises the bottom surface of the via extending beyond the top surface of the conductive line by 10%-35% of the via as measured along a dimension perpendicular to the sidewall of the conductive line.

11. The method of claim 1 wherein forming the via further comprises the bottom surface of the via extending beyond the top surface of the conductive line by 10%-30% of the via as measured along a dimension perpendicular to the sidewall of the conductive line.

12. The method of claim 1 wherein forming the via further comprises the bottom surface of the via extending beyond the top surface of the conductive line by 10%-25% of the via as measured along a dimension perpendicular to the sidewall of the conductive line.

13. The method of claim 1 wherein forming the via further comprises the bottom surface of the via extending beyond the top surface of the conductive line by 10%-20% of the via as measured along a dimension perpendicular to the sidewall of the conductive line.

14. The method of claim 1 wherein a width of the first conductive line is substantially the same as a width of the via.

15. The method of claim 1 wherein a width of the first conductive line is substantially larger than the width of the via.

16. The method of claim 1 wherein a width of the first conductive line is substantially less than the width of the via.

17. A method comprising:
determining a maximum amount of random alignment variation between a first stencil mask and a second stencil mask for a semiconductor device manufacturing process; and
defining a first feature at the first stencil mask to extend beyond a second feature at the second stencil mask in a first dimension by an amount greater than maximum amount of random alignment variation, wherein the first feature defines a via to be formed in electrical contact with a conductive structure to be defined by the second feature.

18. The method of claim 17 wherein defining the first feature includes the first feature defining the via to extend beyond sidewall of the conductive structure by at least 10% of a width of the first structure as measured along a width dimension of the second structure.

19. A method comprising:
forming a semiconductor device at a substrate;
forming a first dielectric layer overlying the substrate;
forming a first conductive line within the first dielectric layer, the first conductive line comprising a first sidewall and a second sidewall abutting the first dielectric layer;
forming a via dielectric layer overlying the first dielectric layer;
forming an opening through the via dielectric layer and within the first dielectric layer to expose the first conductive line; and
forming a via within the opening in electrical contact with the first conductive structure.

20. The method of claim 17 wherein forming the via further comprises forming the via in contact with a sidewall of the first conductive structure.
